(19) United States
(12) Patent Application Publication
(10) Pub. No.: US 2002/0197779 A1
(43) Pub. Date: Dec. 26, 2002

(54) Method of integrating the fabrication of a diffused shallow well N type JFET device and a P channel MOSFET device

(75) Inventor: Ivor Evans, Newport (GB)

Correspondence Address: GEORGE O. SAILE, 20 MCINTOSH DRIVE, POUGHKEEPSIE, NY, 12603, US

(73) Assignee: European Semiconductor Manufacturing Limited

(21) Appl. No.: 09/895,100

(22) Filed: Jul. 2, 2001

(30) Foreign Application Priority Data
Jun. 21, 2001 (GB) 0115251.1

(51) Int. Cl. H01L 21/337

(52) U.S. Cl. 438/186; 438/196

(57) ABSTRACT

A process for integrating the fabrication of an N type, junction field effect transistor (NJFET), device, with the fabrication and a high voltage, P channel metal oxide semiconductor (PMOS), device, has been developed. The process includes the formation of a deep N well region for accommodation of the high voltage, PMOS device, while a shallow N well region is used to contain the NJFET device. Featured in the integrated fabrication sequence is the simultaneous formation of P type source/drain regions for the high voltage PMOS device, and the P type gate structure of the NJFET device.

### BACKGROUND OF THE INVENTION

(1) Field of the Invention

The present invention relates to methods used to fabricate semiconductor devices and more specifically to a method used to integrate the fabrication of a shallow well, n type, junction field effect transistor), NJFET device, with the fabrication of a P channel, metal oxide semiconductor (PMOS), device.

(2) Description of Prior Art

Low voltage, junction field effect transistor (JFET), devices, requiring pinch-off voltages of less then about 5 volts, have been used as a component in integrated circuits for purposes of providing signal processing and analog switching applications. However to maintain, or reduce the fabrication costs of the integrated circuit it is advantageous to integrate the fabrication of the JFET device into the same fabrication sequence used to form other device types used in the integrated circuit. One such device, used for high voltage applications is a high voltage, P channel, metal oxide semiconductor (PMOS), device. This invention will describe a novel process sequence allowing the integration of an N type, JFET, (NJFET), device, with a high voltage PMOS device, without requiring additional photolithographic masking procedures. The integration is accomplished via simultaneous formation of the gate region for the NJFET device, in a standard shallow N well region, with the formation of the drain region of the high voltage PMOS device. Prior art, such as Beason, in U.S. Pat. No. 5,652,153, describe the process used to integrate a JFET device with complimentary bipolar devices. That prior art however does not show the novel integration procedure, described in this present invention, in which a NJFET device is formed during the same processing sequence used to form a PMOS device.

### SUMMARY OF THE INVENTION

It is an object of this invention to use a fabrication sequence which allows simultaneous formation of an NJFET device, and a high voltage PMOS device.

It is another object of this invention to use a shallow N type well to accommodate the NJFET device, while a deep N well region is used to accommodate the high voltage PMOS device.

It is still another object of this invention to simultaneously form the P type gate region of the NJFET device, with the P type drain region of the high voltage PMOS device.

In accordance with the present invention a process used to integrate the fabrication of a NJFET device, in a shallow N well, with the fabrication of a high voltage PMOS device, in a deep N well region, is described. After formation of a deep N well region for the high voltage PMOS device, and a shallow N well region for the NJFET device, a P type region is formed in the NJFET region to be used as the gate region, with P type regions are simultaneously formed for source/drain applications in the PMOS region. After formation of isolation regions, via conventional localized oxidation of silicon (LOCOS), procedures, heavily doped, P type regions are formed in top portions of the NJFET gate region, and in top portions of the high voltage PMOS device. The anode and cathode, or a heavily doped N type, source/drain region, is next formed in regions of the NJFET, shallow N well region. The channel region of the NJFET device is comprised of a portion of the shallow N well region, located in the space between the heavily doped source/drain region and the P type gate region.

### BRIEF DESCRIPTION OF THE DRAWINGS

The object and other advantages of this invention are best described in the preferred embodiment with reference to the attached drawings that include:

FIGS. 1-8, which schematically, in cross-sectional style, describe key stages used to integrate the fabrication of a NJFET device, in a shallow N well region, with the fabrication sequence used for a high voltage PMOS device, formed in a deep N well region.

FIGS. 9-11, which graphically show specific device characteristics of the NJFET structure described in this invention.

### DESCRIPTION OF THE PREFERRED EMBODIMENT

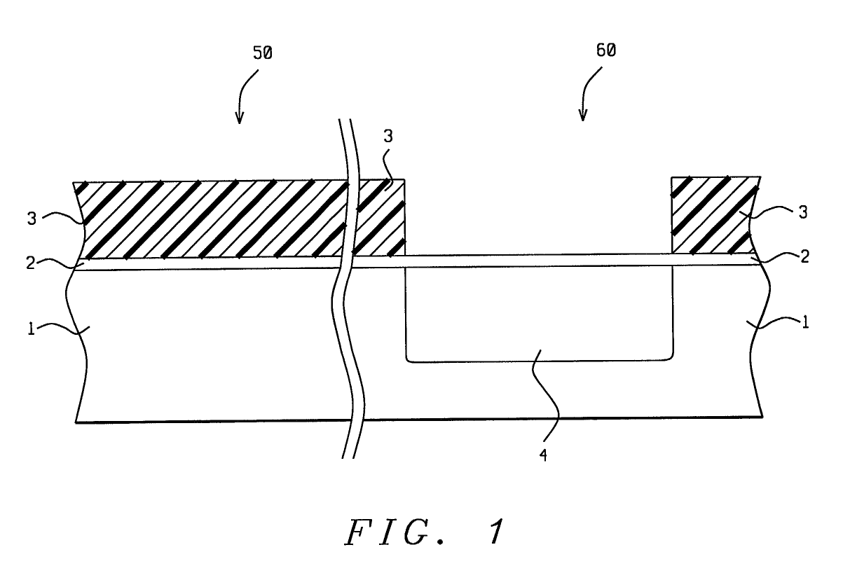

The method of fabricating a N type, junction field effect transistor (NJFET), device, located in a N type shallow well region, simultaneously with the fabrication of a high voltage PMOS device, formed in a deep N well region, will now be described in detail. A P type, semiconductor substrate 1, comprised of single crystalline silicon, featuring a <100> crystallographic orientation, is used and schematically shown in FIG. 1. Region 50, of semiconductor substrate 1, will be used to accommodate the NJFET device, while region 60, of semiconductor substrate 1, will be used to accommodate the high voltage PMOS device. A thin silicon oxide layer 2, to be used as a screen oxide layer for subsequent ion implantation procedures, is thermally grown to a thickness between about 100 to 250 Angstroms. Photoresist shape 3, is next formed with an opening that allows deep N well region 4, to be formed for the high voltage PMOS, in region 60. A deep N well region is needed for the high voltage PMOS device to reduce the risk of punch-through that can occur between subsequent PMOS source/drain regions and the P type substrate. The depth of shallower N well regions, such as the N well region to be used for the NJFET device, if used for the high voltage PMOS device, would allow the unwanted punch-through phenomena to occur. Deep N well region 4, shown schematically in FIG. 1, is achieved via implantation of phosphorous ions, at an energy between about 2 to 4 MeV, at a dose between about 1E12 to 4E12 atoms/cm². Following this photoresist shape 3, is removed via plasma oxygen ashing and careful wet cleans.

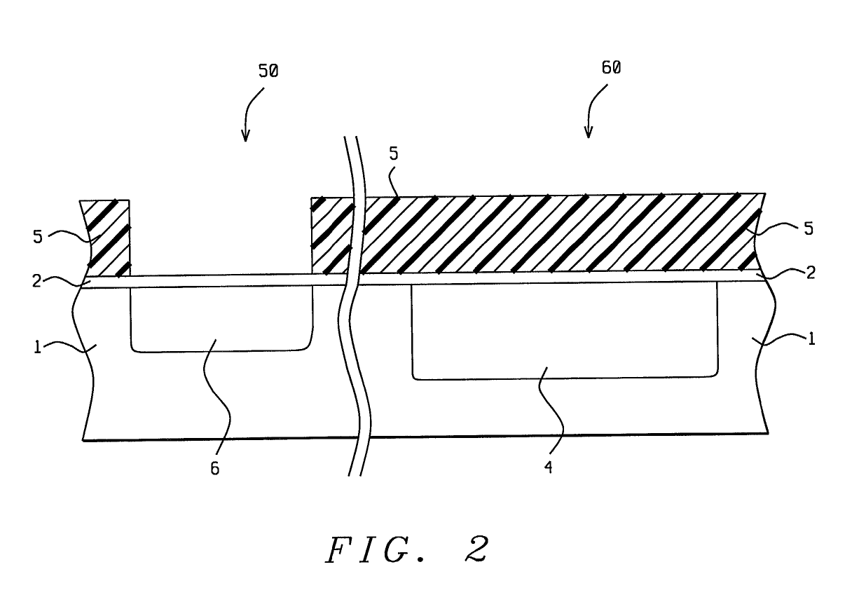

Photoresist shape 5, is next formed and used as an implant mask to allow shallow N well region 6, needed for attainment of optimum NJFET device characteristics, to be formed in region 50, of semiconductor substrate 1. Implantation of phosphorous ions, through the region of screen oxide layer, exposed in the opening in photoresist shape 5, is performed at an energy between about 100 to 200 KeV, at a dose between about 1E12 to 5E12 atoms/cm². After removal of photoresist shape 5, via plasma oxygen ashing and careful wet cleans, a drive-in procedure is performed at a temperature between about 1000 to 1200° C., for a time between about 120 to 200 min., in an argon or nitrogen ambient, resulting in the definition of shallow N well region 6, at a depth between about 3 to 5 um, in region 50, of semiconductor substrate 1. This drive-in procedure also results in the definition of deep well region 4, at a depth between about 5 to 8 um, in region 60 of semiconductor substrate 1. The result of this procedure is schematically shown in FIG. 2. The process for forming the shallow N well region is also used for attainment of a conventional CMOS device structure, as well as for attainment of a diffused resistor layer. This is accomplished during conventional processing methods and is not described further in this application.

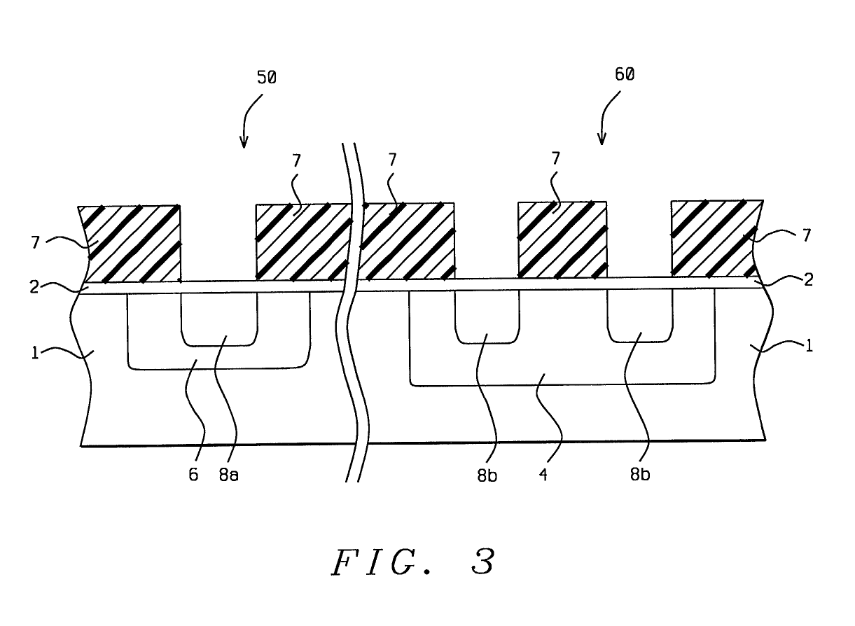

The simultaneous formation of P type source/drain regions, for high voltage PMOS device in region 60, and the gate region for the NJFET device in region 50, is next addressed and schematically shown in FIG. 3. Photoresist shape 7, featuring openings exposing underlying regions of the semiconductor substrate to be used for the PMOS source/drain, and NJFET gate regions, is formed allowing implantation of boron ions, at an energy between about 2 to 4 MeV, and at a dose between about 5E12 to 1E13 atoms/cm², to be performed. After removal of photoresist shape 7, again via plasma oxygen ashing and careful wet clean procedures, an anneal procedure, performed at a temperature between about 1000 to 1200° C., is used to activate the P type ions, resulting in the formation of P type gate region 8a, in shallow N well region 6, in region 50 of semiconductor substrate 1, and simultaneous formation of P type source/drain regions 8b, in deep N well region 4, located in region 60, of semiconductor substrate 1.

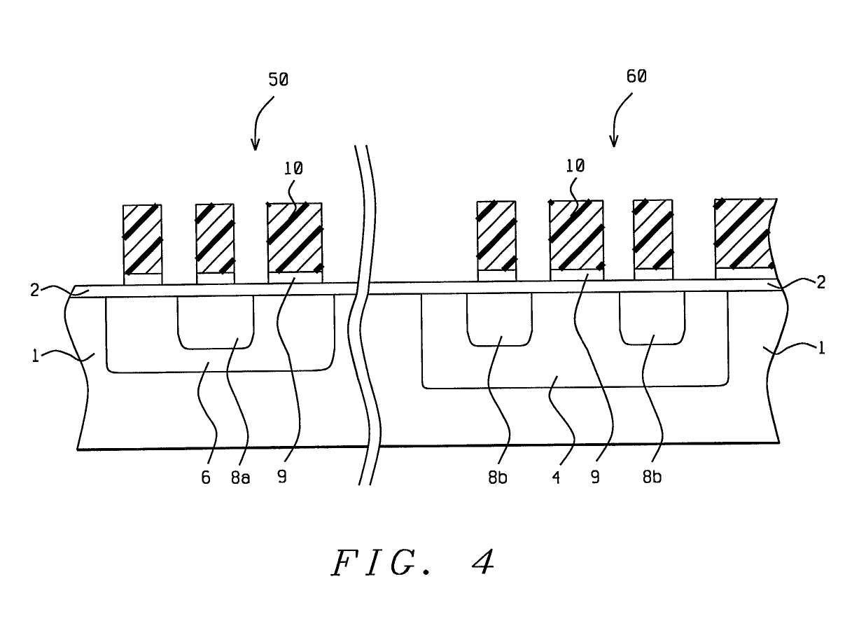

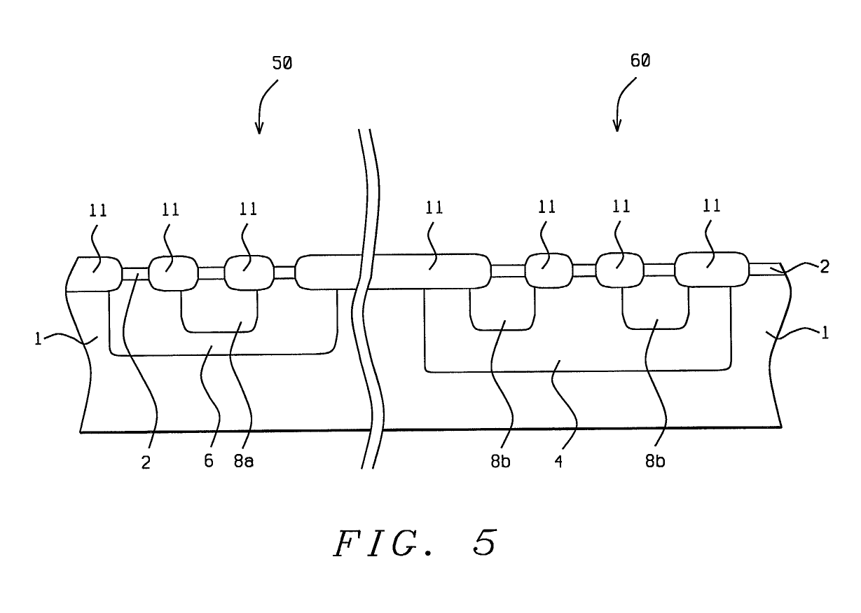

Isolation regions are next formed in specific areas of NJFET device region 50, and high voltage PMOS region 60, via conventional localized oxidation of silicon (LOCOS), procedures. The LOCOS formation is schematically described using FIGS. 4-5. A silicon nitride layer 9, is deposited to a thickness between about 500 to 2000 Angstroms, via low pressure chemical vapour deposition (LPCVD), or plasma enhanced chemical vapour deposition (PECVD), procedures. Photoresist shape 10, is then used as an etch mask to allow regions of silicon nitride 9, to be removed, allowing portions of semiconductor substrate 1, (covered by screen oxide layer 2), to be exposed to a subsequent LOCOS procedure. This is schematically shown in FIG. 4. The patterning of silicon nitride layer 9, is accomplished via a reactive ion etching (RIE), procedure, using Cl₂ or CF₄ as an etchant. After removal of photoresist shape 10, via plasma oxygen ashing and careful wet cleans, an oxidation procedure is performed at a temperature between about 900 to 1100° C., in an oxygen-steam ambient, resulting in the growth of silicon dioxide, or LOCOS isolation shapes 11, at a thickness between about 6000 to 10000 Angstroms, in regions of semiconductor substrate 1, not covered by silicon nitride shapes 9. Selective removal of silicon nitride shapes 9, is next accomplished via use of a hot phosphoric acid solution. The result of the LOCOS formation is schematically shown in FIG. 5.

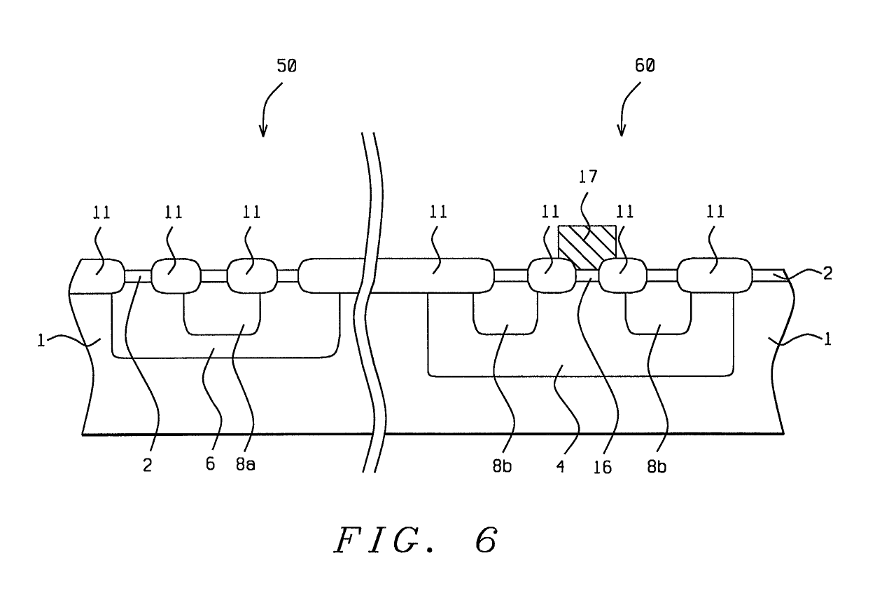

The formation of the gate structure, is next addressed and schematically shown in FIG. 6. Screen oxide layer 2, is first removed via a wet etch procedure using a buffered hydrofluoric acid solution. Gate insulator layer 16, comprised of silicon dioxide, is next thermally grown to a thickness between about 400 to 800 Angstroms, on all exposed silicon surfaces, including formation on the channel region of the high voltage PMOS device, located between P type source/drain regions 8b. A conductive layer, such as a doped polysilicon layer, is deposited via LPCVD procedures, at a thickness between about 3000 to 6000 Angstroms. Conventional photolithographic and RIE procedures, using Cl₂ or SF₆, as an etchant for polysilicon, and using CHF₃ as an etchant for gate insulator layer 16, are used to define polysilicon gate structure 17, on gate insulator 16, located on the channel region of the high voltage PMOS device, in region 60, of semiconductor substrate 1.

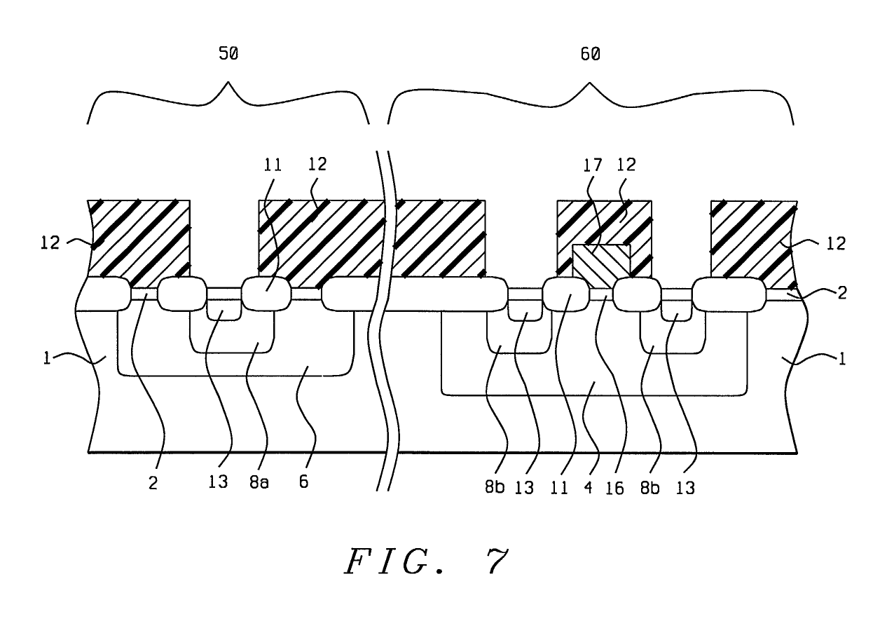

Heavily doped P type regions 13, are next formed in top portions of the PMOS, P type source/drain regions 8a, and in a top portion of the NJFET, P type gate region 8b. The heavily doped P type regions will allow ohmic contact to be realized when overlaid with subsequent metal contact structures. Photoresist shape 12, is formed and used as a mask to allow boron ions, to be implanted at an energy between about 20 to 40 KeV, and at a dose between about 1E15 to 5E15 atoms/cm², in regions of semiconductor substrate 1, not covered by photoresist shape 12. This is schematically shown in FIG. 7.

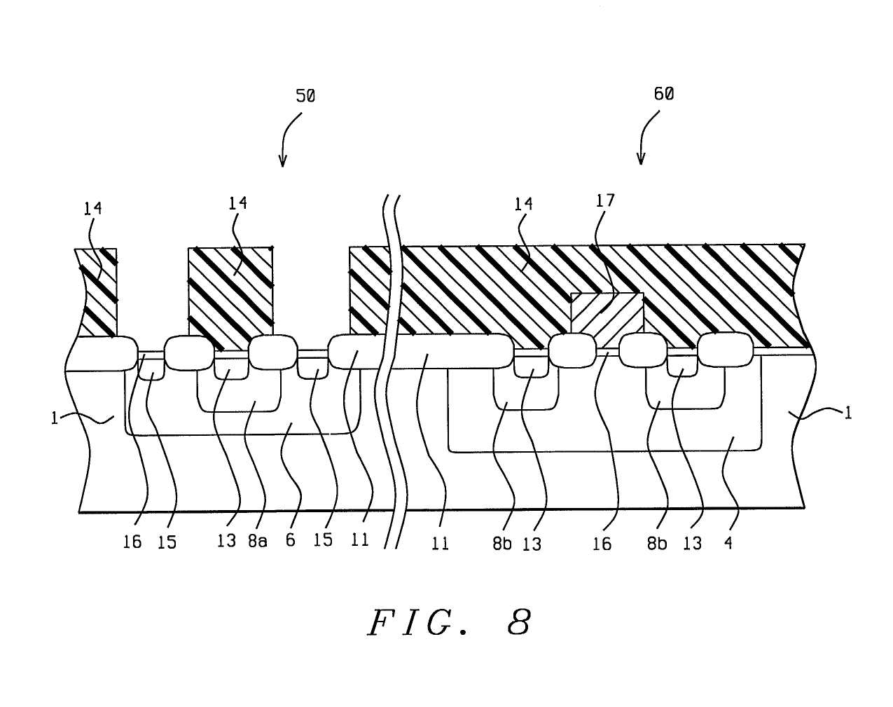

After removal of photoresist shape 12, via plasma oxygen ashing and careful wet cleans, photoresist shape 14, is formed, and used as a mask to allow heavily doped N type regions 15, to be formed in areas of NJFET region 50, not protected by photoresist shape 14, or by LOCOS regions 11. Heavily doped N type regions 15, used as the source/drain, or the anode and cathode, of the NJFET device, are formed via implantation of arsenic or phosphorous ions, at an energy between about 50 to 80 KeV, at a dose between about 1E15 to 5E15 atoms/cm². After removal of photoresist shape 14, via plasma oxygen ashing and careful wet cleans, an anneal procedure is performed at a temperature between about 800 to 950° C., for a time between about 15 to 45 min., in an argon or nitrogen ambient. The anneal results in the activation of P type ions, in heavily doped P type regions 13, the activation of N type ions, located in heavily doped N type regions 15, as well as finalizing the NJFET channel depth. The result of the heavily doped N type implantation and anneal procedures, is schematically shown in FIG. 8.

Subsequent processing, such as deposition of an interlevel dielectric layer, contact hole formation in the interlevel dielectric layer exposing portions of the NJFET and PMOS devices, and the formation of metal contact and interconnect structures, needed for communication to these devices, are performed, but not described or included in the drawings.

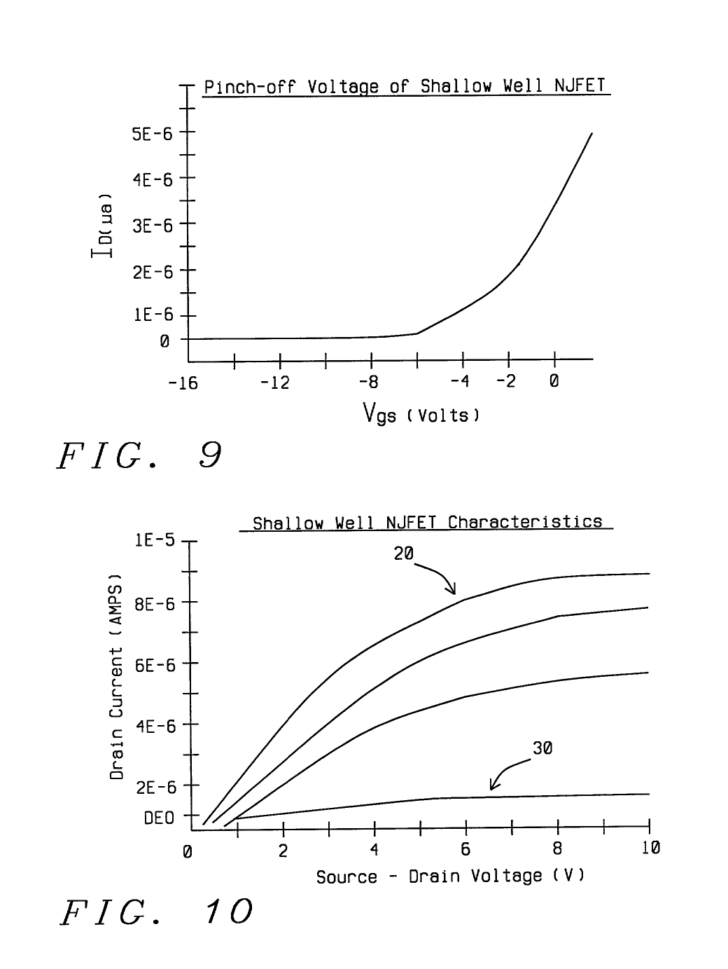

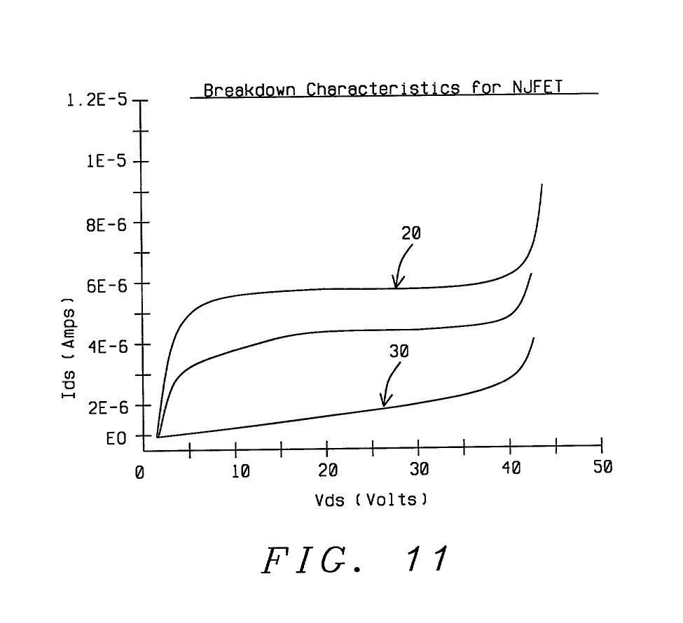

Critical device characteristics of the NJFET device, formed using the procedures described in this present invention, are illustrated in FIGS. 9-11. The pinch-off voltage for the NJFET device, at about −5 volts, is graphically shown in FIG. 9, wherein flow of drain current is restricted for gate voltages of less than −5 volts. FIG. 10, graphically demonstrates the desired IV behaviour of drain current as a function of source/drain voltage, for specific gate voltage values, (where curve 20, is achieved at a lowest gate voltage, and curve 30, at the highest gate voltage. Finally FIG. 11, graphically shows the NJFET device entering breakdown at a source/drain voltage in excess of 40 volts.

While this invention has been particularly shown and described with reference to the preferred embodiments thereof, it will be understood by those skilled in the art that various changes in form and details may be made without departing from the spirit and scope of this invention

What is claimed is:

1. A method of fabricating a N type, junction field effect transistor (NJFET), device, comprising the steps of:
forming a shallow well region of a first conductivity type, in a semiconductor substrate of a second conductivity type;
forming a gate region of a second conductivity type, in a top portion of a first section of said shallow well region;
forming a heavily doped region of a second conductivity type, in a top portion of said gate region; and
forming source/drain regions of a first conductivity type, in top portions of second sections of said shallow well region, with NJFET channel regions located in third sections of said shallow well region, located between said gate region and said source/drain regions.

2. The method of claim 1, wherein said semiconductor substrate is a P type silicon substrate.

3. The method of claim 1, wherein said shallow well region is a shallow N well region, formed via implantation of phosphorous ions, at an energy between about 100 to 200 KeV, at a dose between about 1E12 to 5E12 atoms/cm².

4. The method of claim 1, wherein said gate region is a P type gate region, obtained via implantation of boron ions, at an energy between about 2 to 4 MeV, at a dose between about 5E12 to 1E13 atoms/cm².

5. The method of claim 1, wherein said heavily doped region, located in a top portion of said gate region, is a heavily doped P type region, formed via implantation of boron ions at an energy between about 20 to 40 KeV, at a dose between about 1E15 to 5E15 atoms/cm².

6. The method of claim 1, wherein said source/drain regions are heavily doped, N type source/drain regions, obtained via implantation of arsenic or phosphorous ions, at an energy between about 50 to 100 KeV, at a dose between about 1E15 to 5E15 atoms/cm².

7. A method of integrating the fabrication of an N type, junction field effect transistor (NJFET), device, with the fabrication of a high voltage, P channel metal oxide semiconductor (PMOS), device, on a semiconductor substrate, comprising the steps of:
growing a screen oxide layer on a P type semiconductor substrate;
forming a deep N well region in a first section of said P type semiconductor substrate, wherein said first section is used to accommodate said PMOS device, with said deep N well region formed via a first ion implantation procedure;
forming a shallow N well region in a second section of said P type semiconductor substrate, wherein said second section is used to accommodate said NJFET device, with said shallow N well region formed via a second ion implantation procedure, and via a drive-in procedure;
simultaneously forming P type source/drain regions in top portions of first regions of said deep N well region, and forming a P type gate region in a top portion of a first region of said shallow N well region, with said P type source/drain regions, and P type gate region, formed via a third ion implantation procedure, and via a first activation anneal procedure;
removing said screen oxide layer;
growing a silicon dioxide gate layer in said PMOS region, on a second region of said first section of said P type semiconductor substrate, located between said P type source/drain regions;
forming a gate structure on said silicon dioxide gate layer;
forming heavily doped P type regions in top portions of said P type source/drain regions, and in a top portion of said P type gate region, with said heavily doped P type regions formed via a fourth ion implantation procedure, and via a first activation anneal procedure; and
forming N type source/drain regions in second regions of said shallow N well region, creating a channel region located in a third region of said shallow N well region between said P type gate region and said N type source/drain regions, and with said N type source/drain regions formed via a fifth ion implantation procedure, and via said second activation anneal procedure.

8. The method of claim 7, wherein said screen oxide layer is a silicon oxide layer obtained via thermal oxidation procedures at a thickness between about 100 to 250 Angstroms.

9. The method of claim 7, wherein said first ion implantation procedure, used to form said deep N well region, is performed at an energy between about 2 to 4 MeV, at a dose between about 1E12 to 4E12 atoms/cm², using phosphorous ions.

10. The method of claim 7, wherein said second ion implantation procedure, used to form said shallow N well region, is performed at an energy between about 100 to 200 KeV, at a dose between about 1E12 to 5E12 atoms/cm², using phosphorous ions.

11. The method of claim 7, wherein said drive-in procedure, used to define said deep N well region, is performed at a temperature between about 1000 to 1200° C., for a time between about 120 to 200 min., in an argon or nitrogen ambient.

12. The method of claim 7, wherein said third ion implantation procedure, used to form said P type source/drain regions, and said P type gate region, is performed at an energy between about 2 to 4 MeV, at a dose between about 5E12 to 1E13 atoms/cm², using boron ions.

13. The method of claim 7, wherein said first activation anneal procedure, used to activate P type ions in said P type source/drain regions, and in said P type gate region, is performed at a temperature between about 1000 to 1200° C.

14. The method of claim 7, wherein said silicon dioxide gate layer is thermally grown at a thickness between about 400 to 800 Angstroms.

15. The method of claim 7, wherein said gate structure is comprised of doped polysilicon, formed from a polysilicon layer which in turn is obtained from a LPCVD procedure, at a thickness between about 3000 to 6000 Angstroms, and defined via photolithographic and reactive ion etching procedures, using Cl₂ or SF₆ as an etchant for polysilicon.

16. The method of claim 7, wherein said fourth ion implantation procedure, used to create said heavily doped P type regions in said P type source/drain regions, and in said P type gate region, is performed at an energy between about 20 to 40 KeV, at a dose between about 1E15 to 5E15 atoms/cm², using boron ions.

17. The method of claim 7, wherein said fifth ion implantation procedure, used to create N type source/drain regions, is performed at an energy between about 50 to 100 KeV, at a dose between about 1E15 to 5E15 atoms/cm², using arsenic or phosphorous ions.

18. The method of claim 7, wherein said second activation anneal cycle, used to activate heavily doped P type ions in said heavily doped P type regions, and used to activate N type ions in said N type source/drain regions, is performed at a temperature between about 800 to 950° C., for a time between about 15 to 45 min., in an argon or nitrogen ambient.
